(19) United States
(12) Patent Application Publication
(10) Pub. No.: US 2026/0144019 A1
(43) Pub. Date: May 21, 2026

(54) METHOD AND SYSTEM FOR FORMING A HARD MASK FILM WITH A TUNABLE FILM STRESS

(71) Applicant: TOKYO ELECTRON LIMITED, Tokyo (JP)

(72) Inventors: Tek Po Rinus LEE, Albany, NY (US); Kenichi IMAKITA, Albany, NY (US); Ayuta SUZUKI, Albany, NY (US)

(73) Assignee: TOKYO ELECTRON LIMITED, Tokyo (JP)

(21) Appl. No.: 18/949,622

(22) Filed: Nov. 15, 2024

(51) Int. Cl. H01L 21/033; H01L 21/311; H01L 21/3213

(52) U.S. Cl. CPC H10P 76/405; H10P 50/71; H10P 50/73

(57) ABSTRACT

This disclosure provides a method of forming a hard mask film over a semiconductor device. The method includes determining a film stress of the hard mask film based on an internal stress of the semiconductor device, performing a tungsten silicide (WSi) deposition at a cryogenic temperature over the semiconductor device to form the hard mask film, determining a time period of an annealing process to be performed based on the determined film stress of the WSi hard mask film, and performing the annealing process to the WSi hard mask film based on the determined time period.

### TECHNICAL FIELD

This disclosure relates generally to formation of hard mask films, and particularly to techniques for forming a hard mask film with a tunable film stress.

### BACKGROUND

Semiconductor fabrication involves many different steps of depositing, growing, patterning, removal, and cleaning of wafers. The patterning of a semiconductor device needs a mask as a sacrificial layer. A deep vertical pattern of the semiconductor device is often performed by a plasma-based etching process. As an aspect ratio of the deep vertical pattern in the semiconductor device increases, the mask requires a higher etch selectivity to resist the plasma-based etching process. A hard mask is generally more etch resistant to plasma reactive gases than conventional organic soft masks for the deep patterning.

### SUMMARY

This disclosure provides a method of forming a hard mask film over a semiconductor device. The method includes determining a film stress of the hard mask film based on an internal stress of the semiconductor device, performing a tungsten silicide (WSi) deposition at a cryogenic temperature over the semiconductor device to form the hard mask film, determining a time period of an annealing process to be performed based on the determined film stress of the WSi hard mask film, and performing the annealing process to the WSi hard mask film based on the determined time period.

This disclosure provides a semiconductor processing system for forming a hard mask film over a semiconductor device. The semiconductor processing system includes a controller configured to determine a film stress of the hard mask film based on an internal stress of the semiconductor device, perform a WSi deposition at a cryogenic temperature over the semiconductor device to form the hard mask film, determine a time period of an annealing process to be performed based on the determined film stress of the WSi hard mask film, and perform the annealing process to the WSi hard mask film based on the determined time period.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1D shows an etch process using a hard mask film according to an embodiment of the disclosure.

FIG. 2 shows a film stress comparison of tungsten silicide hard mask films formed at room temperature and cryogenic temperature according to an embodiment of the disclosure.

FIG. 3 shows a semiconductor processing system according to an embodiment of the disclosure.

FIG. 4 illustrates a process of forming a hard mask film according to an embodiment of the disclosure.

### DETAILED DESCRIPTION

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

A hard mask film can be used as a sacrificial layer in lithographic patterning of a vertical semiconductor device with a high aspect ratio, such as a three dimensional (3D) memory device. Through an etch process, the hard mask film can enable vertical patterns in the semiconductor device.

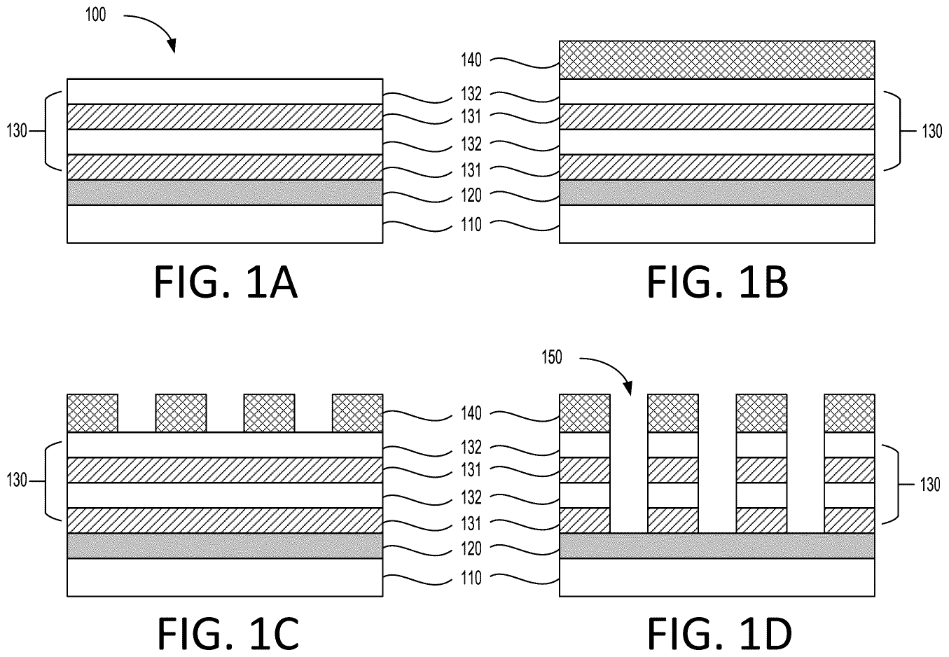

FIGS. 1A-1D show an etch process using a hard mask film according to an embodiment of the disclosure. Specifically, FIG. 1A shows a vertical semiconductor device 100, such as a 3D NAND or dynamic random access memory (DRAM) device. The semiconductor device 100 can include a substrate 110. The substrate 110 can be a silicon-based substrate or include any suitable insulating material or conductive material as needed.

Over the substrate 110, the semiconductor device 100 can include an etch stop layer 120. The etch stop layer 120 can stop the etching and may include a non-conducting material such as titanium nitride (TiN), tantalum nitride (TaN), tungsten nitride (WN), titanium silicon nitride (TiSiN), tantalum silicon nitride (TaSiN), silicon carbide (SiC), silicon nitride (SiN), nitrogen doped carbide (NDC), or oxygen doped carbide (ODC).

Over the etch stop layer 120, the semiconductor device 100 can include a film stack 130 including alternating layers 131 and 132. In an embodiment, the alternating layers 131 and 132 can be conducting layers (e.g., copper, aluminum, or polysilicon) and insulating layers (e.g., silicon oxide), respectively. In an embodiment, the alternating layers 131 and 132 can be sacrificial layers (e.g., silicon nitride) and insulating layers (e.g., silicon oxide), respectively.

It is noted that the semiconductor device 100 can include one or more other layers that are not shown in FIG. 1A. The film stack 130 is not limited to include the alternating layers 131 and 132, and can include any other layers as needed. Further, the semiconductor device 100 may not include the etch stop layer 120 in an embodiment.

In FIG. 1B, a hard mask film 140 can be formed over the film stack 130, for example, using a film deposition process, such as physical vapor deposition (PVD), chemical vapor deposition (CVD), plasma-enhanced chemical vapor deposition (PECVD), or atomic layer deposition (ALD).

In FIG. 1C, the hard mask film 140 can be patterned with one or more openings to define where features are to be etched in the semiconductor device 100.

In FIG. 1D, the film stack 130 can be etched based on the patterned hard mask film 140. The etching can stop at the etch stop layer 120. Through the etching, one or more deep trenches 150 can be formed.

According to aspects of the disclosure, a by-product can be formed during the patterning of the hard mask film. For example, when patterning a titanium nitride (TiN) hard mask film, a by-product titanium tetrafluoride (TiF₄) can be formed. During the etching of the film stack 130, the by-product TiF4 may be left in the deep trenches 150 and degrade the etching performance. Accordingly, a volatile by-product is desired for forming the hard mask film.

Further, a film stress of the hard mask film is also important for forming the hard mask film. A high compressive or tensile stress can lead to a film buckling or delamination. However, in some cases, a hard mask film with a high stress (either tensile or compressive) may be needed, for example, to compensate a stress of a semiconductor device that the hard mask film is to be formed over. The semiconductor device may have a high compressive or tensile stress after being processed through various processing steps, and thus needs the hard mask film to provide a complimentary stress to compensate the high compressive or tensile stress. For example, if the semiconductor device has a high compressive stress, a hard mask film with a high tensile stress is desired. The film and substrate stress can be measured, for example, through an optical measurement. For example, the wafer warpage can be measured through a laser light reflected off a wafer into a detector and the wafer stress can be calculated from the measurement.

This disclosure provides techniques of forming a hard mask film with a tunable stress and a volatile by-product. In this disclosure, tungsten silicide (WSi) is used as a material of the hard mask film. A by-product of patterning the WSi hard mask film is tungsten hexafluoride (WF₆), which is volatile and thus very easy to be removed from a deep trench that is formed by using the WSi hard mask film.

According to aspects of the disclosure, the WSi hard mask can be formed at a cryogenic temperature (e.g., between 50K and 150K). A film stress of the WSi hard mask film can be tuned by an annealing process. Specifically, the film stress of the WSi hard mask film can be determined based on an internal stress of a semiconductor device that the WSi hard mask film is to be formed over. After the film stress of the WSi hard mask film is determined, a time period of the annealing process can be determined based on the determined film stress of the WSi hard mask film. As the film stress of the WSi hard mask film increases, the time period of the annealing process can increase. Then, based on the determined time period, the annealing process can be performed to the WSi hard mask film to obtain the desired film stress for the WSi hard mask film.

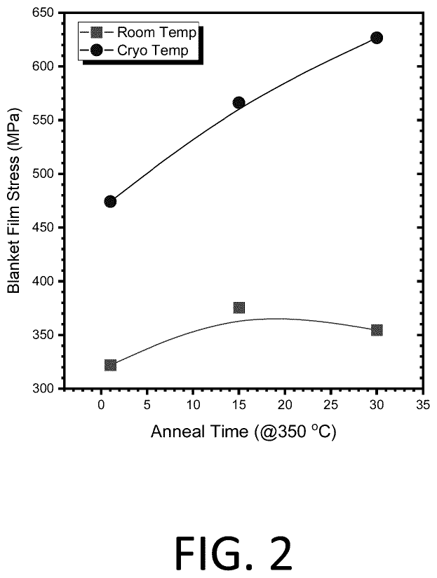

FIG. 2 shows a film stress comparison of WSi hard mask films formed at room temperature and cryogenic temperature according to an embodiment of the disclosure. As shown in FIG. 2, the film stress of the WSi hard mask film formed at the cryogenic temperature can almost linearly increase from 470 MPa to 630 MPa within 30 mins of the annealing process that is performed at 350° C. However, the film stress of the WSi hard mask film formed at the room temperature can be around 320 MPa when the annealing process starts, peak at 375 MPa after 15 mins of the annealing process, and then saturate to 350 MPa after 30 mins of the annealing process. Accordingly, the film stress of the WSi hard mask film formed at the cryogenic temperature can have a range of 160 MPa, which is almost a triple of 55 MPa of the range of the film stress of the WSi hard mask film formed at the room temperature.

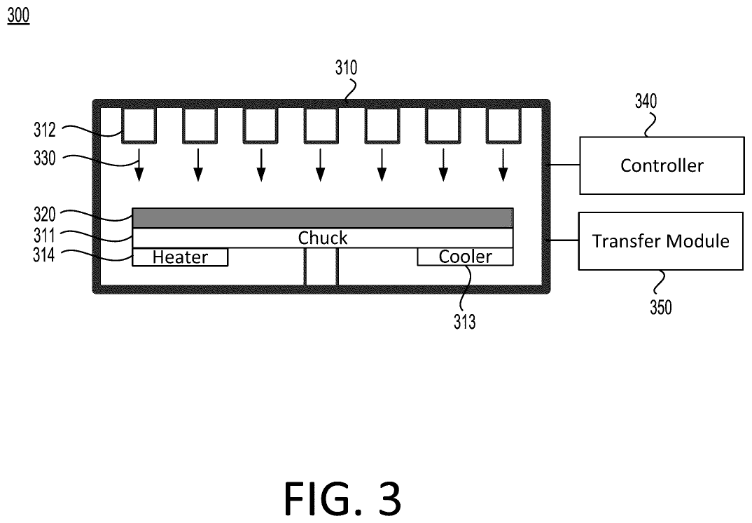

FIG. 3 shows a semiconductor processing system 300 according to an embodiment of the disclosure. The semiconductor processing system 300 can include a process chamber 310. The process chamber 310 can include an electrostatic chuck 311 that can hold a semiconductor wafer 320. The process chamber 310 can include one or more nozzles 312 that can deposit hard mask material 330 onto the semiconductor wafer 320 to form a hard mask film. The process chamber 310 can include a cooler 313 and a heater 314 to adjust the inside temperature of the process chamber 310. In an embodiment, the cooler 313 can be used to perform the hard mask film deposition at a cryogenic temperature to form the hard mask film. In an embodiment, the heater 314 can be used to perform an annealing process to tune a film stress of the hard mask film.

The semiconductor processing system 300 can include a controller 340 that is configured to control the operations of the process chamber 310. The controller 340 can control the electrostatic chuck 311 to hold the semiconductor wafer 320. The controller 340 can control the nozzles 312 to deposit the hard mask material 330 onto the semiconductor wafer 320. The controller 340 can control the cooler 313 to decrease the temperature of the semiconductor wafer 320 to a cryogenic temperature (e.g., between 50K and 150K) so that the hard mask film deposition can be performed at the cryogenic temperature. The controller 340 can control the heater 314 to increase the temperature of the semiconductor wafer 320 to an annealing temperature (e.g., 700K) so that the annealing process can be performed at the annealing temperature.

The semiconductor processing system 300 can include a transfer module 350 that is configured to load and unload the semiconductor wafer 320 into and out of the process chamber 310. The semiconductor processing system 300 can include a degassing unit 360 configured to perform a degassing process with respect to a processing target, for example, the semiconductor wafer 320.

It is noted that the process chamber 310 may not include the cooler 313 or the heater 314 in an embodiment. If the process chamber 310 does not include the cooler 313, the hard mask film deposition can be performed in another process chamber and the annealing process can be performed in the process chamber 310. If the process chamber 310 does not include the heater 314, the annealing process can be performed in another process chamber and the hard mask film deposition can be performed in the process chamber 310.

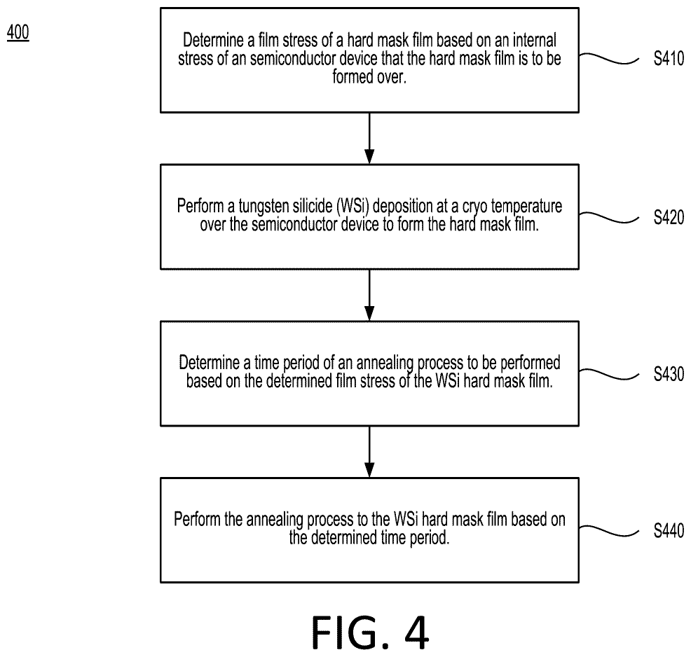

FIG. 4 illustrates a process 400 of forming a hard mask film (e.g., the hard mask film 140) over a semiconductor device (e.g., the semiconductor device 100) according to an embodiment of the disclosure. The process 400 can be implemented by a semiconductor processing system (e.g., the semiconductor processing system 300). The process 400 can be implemented as instructions stored in a non-transitory computer-readable medium. When executed by for example the semiconductor processing system, the instructions can cause the semiconductor processing system to perform the process 400. The process 400 may start at step S410.

At step S410, the process 400 can determine a film stress of the hard mask film based on an internal stress of the semiconductor device. In an embodiment, the film stress of the hard mask film can be determined to be complementary to the internal stress of the semiconductor device. In an example, if the semiconductor device has a high tensile or compressive stress, the hard mask film can be formed to have a high compressive or tensile stress. In an example, if the semiconductor device has a low tensile or compressive stress, the hard mask film can be formed to have a low compressive or tensile stress. Then, the process 400 can proceed to step S420.

At step S420, the process 400 can perform a WSi deposition at a cryogenic temperature (e.g., between 50K and 150K) over the semiconductor device 100. In an embodiment, the WSi deposition can be performed, for example, using a film deposition process such as PVD, CVD, PECVD, ALD, or the like. In an embodiment, the semiconductor device can include a substrate (e.g., the substrate 110) and a film stack formed over the substrate (e.g., the film stack 130). The WSi hard mask film can be formed over the film stack formed over the substrate of the semiconductor device. In an example, the film stack can include alternating insulating layers (e.g., silicon oxide) and conducting layers (e.g., copper, aluminum, or polysilicon). In an embodiment, the film stack can include alternating insulating layers and sacrificial layers (e.g., silicon nitride). Then, the process 400 can proceed to step S430.

At step S430, the process 400 can determine a time period of an annealing process to be performed based on the determined film stress of the WSi hard mask film. For example, based on the measurement in FIG. 2, for a desired film stress, the time period of the annealing process can be determined. An annealing temperature of the annealing process can be set as 350° C. (623K). Then, the process 400 can proceed to step S440.

At step S440, the process 400 can perform the annealing process (e.g., at 350° C.) to the WSi hard mask film based on the determined time period.

In an embodiment, the process 400 can pattern the WSi hard mask film and etch semiconductor device based on the patterned WSi hard mask film. For example, as shown in FIGS. 1C and 1D, the WSi hard mask film can be patterned, and the film stack formed over the substrate can be etched based on the patterned WSi hard mask film.

In an embodiment, the WSi deposition and the annealing process can be performed in a same process chamber.

In an embodiment, the WSi deposition and the annealing process can be performed in different process chambers.

In an embodiment, the WSi deposition can include an inert gas (e.g., argon).

Aspects of the disclosure provide a semiconductor processing system for forming a hard mask film over a semiconductor device. The semiconductor processing system includes a controller configured to determine a film stress of the hard mask film based on an internal stress of the semiconductor device, perform a WSi deposition at a cryogenic temperature over the semiconductor device to form the hard mask film, determine a time period of an annealing process to be performed based on the determined film stress of the WSi hard mask film, and perform the annealing process to the WSi hard mask film based on the determined time period.

In an embodiment, the determined film stress of the hard mask film is complementary to the internal stress of the semiconductor device.

In an embodiment, the controller is further configured to pattern the WSi hard mask film and etch the semiconductor device based on the patterned WSi hard mask film.

In an embodiment, the cryogenic temperature is between 50K and 150K.

In an embodiment, the semiconductor device includes a substrate and a film stack over the substrate. The WSi hard mask film is formed over the film stack formed over the substrate. In an example, the film stack includes alternating insulating layers and conducting layers. In an example, the film stack includes alternating insulating layers and sacrificial layers.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A method of forming a hard mask film over a semiconductor device, the method comprising:
determining a film stress of the hard mask film based on an internal stress of the semiconductor device;
performing a tungsten silicide (WSi) deposition at a cryogenic temperature over the semiconductor device to form the hard mask film;
determining a time period of an annealing process to be performed based on the determined film stress of the WSi hard mask film; and
performing the annealing process to the WSi hard mask film based on the determined time period.

2. The method of claim 1, wherein the determined film stress of the hard mask film is complementary to the internal stress of the semiconductor device.

3. The method of claim 1, further comprising:
patterning the WSi hard mask film; and
etching the semiconductor device based on the patterned WSi hard mask film.

4. The method of claim 1, wherein the cryogenic temperature is between 50K and 150K.

5. The method of claim 1, wherein the semiconductor device includes a substrate and a film stack formed over the substrate.

6. The method of claim 5, wherein the WSi hard mask film is formed over the film stack formed over the substrate.

7. The method of claim 5, wherein the film stack includes alternating insulating layers and conducting layers.

8. The method of claim 5, wherein the film stack includes alternating insulating layers and sacrificial layers.

9. The method of claim 1, wherein the WSi deposition and the annealing process are performed in a same process chamber.

10. The method of claim 1, wherein the WSi deposition and the annealing process are performed in different process chambers.

11. A semiconductor processing system for forming a hard mask film over a semiconductor device, the semiconductor processing system comprising:
a controller configured to
determine a film stress of the hard mask film based on an internal stress of the semiconductor device,
perform a tungsten silicide (WSi) deposition at a cryogenic temperature over the semiconductor device to form the hard mask film,
determine a time period of an annealing process to be performed based on the determined film stress of the WSi hard mask film, and
perform the annealing process to the WSi hard mask film based on the determined time period.

12. The semiconductor processing system of claim 11, wherein the determined film stress of the hard mask film is complementary to the internal stress of the semiconductor device.

13. The semiconductor processing system of claim 11, wherein the controller is further configured to:
pattern the WSi hard mask film; and
etch the semiconductor device based on the patterned WSi hard mask film.

14. The semiconductor processing system of claim 11, wherein the cryogenic temperature is between 50K and 150K.

15. The semiconductor processing system of claim 11, wherein the semiconductor device includes a substrate and a film stack formed over the substrate.

16. The semiconductor processing system of claim 15, wherein the WSi hard mask film is formed over the film stack formed over the substrate.

17. The semiconductor processing system of claim 15, wherein the film stack includes alternating insulating layers and conducting layers.

18. The semiconductor processing system of claim 15, wherein the film stack includes alternating insulating layers and sacrificial layers.

19. The semiconductor processing system of claim 11, wherein the WSi deposition and the annealing process are performed in a same process chamber.

20. The semiconductor processing system of claim 11, wherein the WSi deposition and the annealing process are performed in different process chambers.
